(19) United States
(12) Patent Application Publication
(10) Pub. No.: US 2012/0276344 A1
(43) Pub. Date: Nov. 1, 2012

(54) METHOD OF MAKING A PATTERNED DRIED POLYMER AND A PATTERNED DRIED POLYMER

(76) Inventors: Joseph Keddie, London (GB); Argyrios Georgiadis, Guildford (GB)

(21) Appl. No.: 13/505,181

(22) PCT Filed: Oct. 18, 2010
(86) PCT No.: PCT/GB2010/001923

§ 371 Date: Jul. 16, 2012

(30) Foreign Application Priority Data
Oct. 29, 2009 (GB) 0918976.2

(51) Int. Cl. G03F 7/20; B32B 3/10; B82Y 40/00

(52) U.S. Cl. 428/195.1; 430/322; 977/901

(57) ABSTRACT

A method of making a patterned dried polymer from a polymer solution or polymer dispersion, the method comprising the step of placing a mask above the polymer solution/dispersion so that there are exposed areas of polymer solution/dispersion and unexposed areas of polymer solution/dispersion, and irradiating the masked polymer solution/dispersion with infrared radiation.

The invention relates to a method of making a patterned dried polymer from a polymer solution or polymer dispersion and to a patterned dried polymer made by that method. The patterned dried polymer will usually be in the form of a coating on a substrate or a free-standing sheet or film.

The method of the invention is particularly useful for making patterned dried latex coatings or films, and is applicable to both hard latexes (i.e. latexes where the polymer has a glass transition temperature (T_{g}) above room temperature) and soft latexes (i.e. latexes where the polymer has a glass transition temperature (T_{g}) below room temperature). A latex is defined here as a synthetic polymer colloid dispersed in water.

Hard polymers are used to make protective coatings in many industries, including the automotive, aerospace, shipping, home appliance and furniture industries. Hard coatings can be made from a hard latex. Hard polymer coatings having a topographically patterned surface may be required for a number of different purposes. For example, they may be required to provide an aesthetic effect, to increase grip and friction, or to affect the scattering and transmission of electromagnetic radiation. Soft latexes are used to make flexible products such as gloves and condoms. Again, a topographically patterned surface may be required to provide an aesthetic effect, or to increase grip. Alternatively, it may be required to increase tactile sensation. Soft latex films are also used to make pressure-sensitive adhesives. Patterning on the adhesive surface could alter the tackiness and adhesion energy of the adhesive, and be used either to promote or to decrease adhesion to the surface.

Besides the applications mentioned above, topographically patterned coatings have applications as anti-fouling coatings, such as are used in the marine and ship-building industry. Moreover, corrugated surfaces with certain pitches are known to reduce hydrodynamic drag on ships. Other possible applications are to provide a light diffusing film for coating a window for added privacy, or to provide an array of micro-lenses on a surface to increase light emission from a device or to otherwise manipulate light.

In the case of hard latexes, it is known to make a pattern in the surface of a coating by an embossing process in which a hot mould is pressed onto the surface of the coating to melt and to shape it. However, such an embossing process is not suitable for fragile or thermally-unstable substrates and is not very practical over a large area. Moreover, the energy use of the embossing process will be significant if the polymer surface has a high T_{g}.

In the case of soft latexes, it is known to use a two-stage process where droplets of latex are sprayed onto the surface of a base layer of latex to create a textured pattern. However, this process is time consuming and it has limitations in the type of patterns that are possible as it cannot be used to make a bespoke pattern.

It is an object of the invention to seek to mitigate these disadvantages.

Accordingly, the invention provides a method of making a patterned dried polymer from a polymer solution or polymer dispersion, the method comprising the step of placing a mask above the polymer solution/dispersion so that there are exposed areas of polymer solution/dispersion and unexposed areas of polymer solution/dispersion, and irradiating the masked polymer solution/dispersion with infrared radiation.

The invention relies on the fact that the evaporation rate of solvent (water in the case of a latex) will be different in the exposed and unexposed areas of polymer solution/dispersion. The evaporation rate will be higher in the exposed areas, and so the solid content in these areas will become higher than in the unexposed areas. There will be a flux of fluid from the unexposed areas to the exposed areas to replace the lost solvent (such as water in the case of a latex). This flux will carry polymer particles/molecules with it, and so the exposed areas will become raised relative to the unexposed areas. These raised portions will form a pattern on the surface of the resulting dried polymer.

The invention may be applied to any suitable polymer solution/dispersion. For example, it may be used to pattern a polymer that is molecularly dissolved in a solvent, such as water. Variations in evaporation rate caused by localised heating by infrared radiation lead to the formation of a topographical pattern on the surface of the resulting polymer film. Examples of suitable water-soluble polymers are poly(vinyl alcohol), poly(acrylic acid), poly(vinyl pyrrolidone), poly(ethylene oxide), poly(styrene sulfonate) and poly(3-4 ethylene dioxythiophene).

As well as water, other suitable solvents, such as ethyl alcohol, may be used. Whatever the solvent, the concentration of the polymer should preferably be in the range of 0.01 to 90 wt. %, more preferably in the range from 0.1 to 50 wt. %, and most preferably in the range from 1 to 15 wt. %.

Although the invention may be applied to polymer solutions, the primary application of the invention is to polymer dispersions in the form of a latex.

A “wet” latex consists of an aqueous dispersion of colloidal polymer particles, typically having a diameter of about 100 to 400 nm. A “dried” latex is formed from a “wet” latex by a process which is usually referred to as “latex film formation”. This process consists of the following stages: (1) evaporation of water and particle packing; (2) particle deformation to close the voids between the particles; and (3) diffusion of molecules across the particle boundaries to erase the interfaces. Stage 2 can be referred to as “sintering” and stage (3) can be referred to as “coalescence”. Latex films are cloudy when the particles have not sintered (because of light scattering), but they become clear after sintering.

Particles will not be deformed and molecules will not diffuse at temperatures below the polymer glass transition temperature (T_{g}). This means that only low T_{g} latexes will film form at room temperature. High T_{g} latexes can be heated to make them film form. In the past, the heating of latex films has been done using conventional convection ovens. However this has the following disadvantages: (1) the high energy use of the ovens, (2) the length of the process unless very high temperatures are used, and (3) the tendency for the films to crack during drying.

The applicant has found that these disadvantages may be mitigated if the latex is heated using infrared radiation. Applying infrared radiation through a mask allows the localised heating of a latex, which allows the creation of a bespoke pattern. The term “infrared radiation” as used herein means radiation of wavelength in the range of 0.7 μm and 30 μm.

Polymers and water absorb infrared radiation strongly at certain characteristic wavelengths. When the water absorbs the radiation, it will increase in temperature. The evaporation rate of water will therefore increase under infrared radiation. This also means that, if a latex is exposed to infrared radiation, then the polymer particles will absorb the radiation and increase in temperature. The polymer particles will then soften and be able to sinter and coalesce to create a film.

The main advantages of using infrared radiation are that it enables film formation of hard latex particles, and it increases the evaporation rate in the unmasked regions of a wet latex. Also, infrared radiation leads to a faster evaporation rate in the irradiated areas and therefore a higher flux of solvent. Consequently, topographical patterns are stronger with infrared radiation, and they are weaker when evaporation occurs naturally. In addition to these advantages, an infrared lamp typically uses less energy than a convection oven, and so the process of the present invention is more energy efficient than using a convection oven. Moreover, the process is quicker than using a convection oven. In addition, there is a reduced tendency for the films to crack during drying.

Although the use of infrared radiation is particularly useful for hard latexes, it is also useful for soft latexes because it increases the water evaporation rate.

Thus, the latex may be a hard latex having a T_{g} in the range from 20° C. to 100° C. Alternatively, the latex may be a soft latex having a T_{g} in the range from −50° C. to 20° C.

As the temperature of the latex increases above the T_{g}, the polymer viscosity decreases, and the deformation and diffusion stages are faster. As the temperature increases, water evaporates faster. The applicant has found that if water evaporates at a temperature less than the T_{g}, then film cracking is likely to result, but at temperatures above the T_{g}, then films are less subject to cracking. The applicant believes that this is because of stress created by capillary forces when hard particles do not deform from their spherical shape.

Accordingly, the exposure conditions are preferably such that the temperature of the polymer is raised above its glass transition temperature, more preferably at least 15° C. above its glass transition temperature.

The temperature of the polymer will be affected by the conditions under which the latex is exposed to the infrared radiation, such as the wavelength of the infrared radiation, the intensity of the infrared radiation, the length of exposure to the infrared radiation and the distance between the infrared source and the latex coating. Accordingly, these parameters may be adjusted as required in order to obtain the desired results.

The wavelength should preferably be at the wavelength at which the polymer and/or water has the greatest absorption coefficient. Alternatively, the wavelength of the infrared radiation should preferably be in the range from 0.7 μm to 30 μm, more preferably in the range from 0.7 μm to 1.8 μm.

The exposure time should be adjusted to a length that is suitable for a particular latex thickness and composition. Preferably, the masked latex should be exposed to the infrared radiation until the latex is completely dried.

The distance of the latex from the infrared source should be adjusted depending on the type of infrared lamp, and the composition of the polymer. Preferably, the distance of the latex from the infrared source is in the range between 1 and 100 cm, more preferably between 5 and 30 cm, and most preferably 15 to 25 cm.

Preferably, the latex is in the form of a coating. Preferably, the thickness of the dry latex is in the range between 0.5 μm and 1 cm thick, more preferably between 2 μm and 1 mm thick and most preferably in the range between 10 μm and 300 μm thick.

Preferably, the solids content of the latex is in the range from 10 weight percent to 80 weight percent, preferably in the range from 30 weight percent to 60 weight percent, more preferably in the range from 45 weight percent to 55 weight percent.

Preferably, the distance between the latex and the mask should be in the range from 0.01 mm to 10 cm, preferably in the range from 0.1 mm to 10 mm, and more preferably in the range from 0.2 mm to 3 mm. If the distance between the latex and the mask is too large, then this will result in the modulation of the evaporation rate being lessened, so that pattern formation will be inhibited or prevented.

The shape of the perforations in the mask and their arrangement in relation to each other may be altered according to the pattern which is to be generated on the surface of the latex.

The perforations in the mask may be of any suitable size. For example, they may have a diameter in the range from 0.01 mm to 10 cm, preferably in the range from 0.1 mm to 1 cm, and more preferably in the range from 0.5 mm to 5 mm.

The perforations in the mask may be of any suitable shape. For example, they may be square, circular, triangular, rectangular, polygonal, or in the shape of a logo.

The mask may be of any suitable size. For example, it may have dimensions ranging from 1 mm to 10 m, preferably in the range from 1 cm to 1 m, and more preferably in the range from 1 cm to 20 cm.

Preferably, the mask fully covers the latex.

The mask may be made from any suitable material that will block the transmission of infrared radiation. For example it may be made from steel, aluminium, card, wood, plastic or glass.

The mask may be constructed such that the area around the perforation is semi opaque to IR. This area may be the same or different in shape to the perforation and the diameter of the semi opaque area can be presented in a range of sizes.

A first mask made from material that is semi opaque to IR with small perforations may be overlaid with a second mask opaque to IR which has larger perforations than the semi opaque mask, the resulting arrangement being such that a larger perforation or perforations on the opaque mask encircles the smaller perforation or perforations on the semi opaque mask resulting in the creation of a semi opaque area around the smaller perforation.

More than one mask may be used to produce the desired pattern or patterns on the substrate. The multiple masks may have the same or different perforation sizes and shapes.

The substrate may be pre-coated in a particular pattern with a water repellent material before adding a coating of polymer solution or polymer dispersion and drying with IR through any of the masks previously described.

The latex may be cast on any suitable substrate. For example, it may be cast on a substrate made of glass, steel, aluminium, plastic, card or wood.

Where the latex is a soft latex, the latex may be removed from the substrate to make a free-standing film.

The latex may comprise a mixture of two or more latexes, each having a different average particle size.

The latex may comprise one or more of the following: metallic nanoparticles, semiconducting particles, coloured particles, fluorescent particles, an additional infrared absorber such as poly(3,4-ethylenedioxythiopene)/poly(styrene sulfonate), known as PEDOT:PSS.

Although the paragraphs set out above refer to a “latex”, they apply equally to polymer solutions and other polymer dispersions.

The invention will now be illustrated, by way of example only, with reference to the following figures:

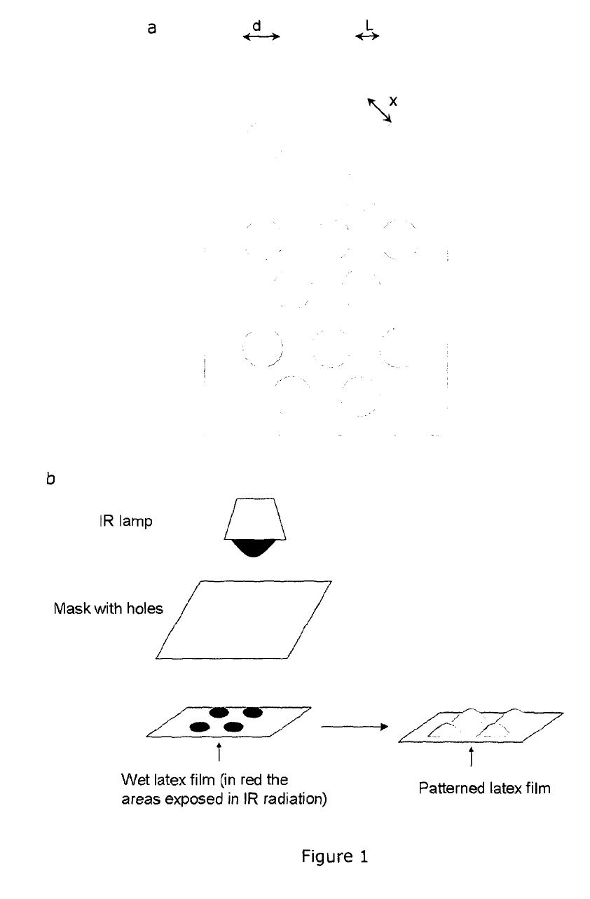

FIG. 1a shows a diagram of the mask used for Example 1 (not drawn to scale);

FIG. 1b shows schematically a masked latex being exposed to IR radiation according to the method of the invention;

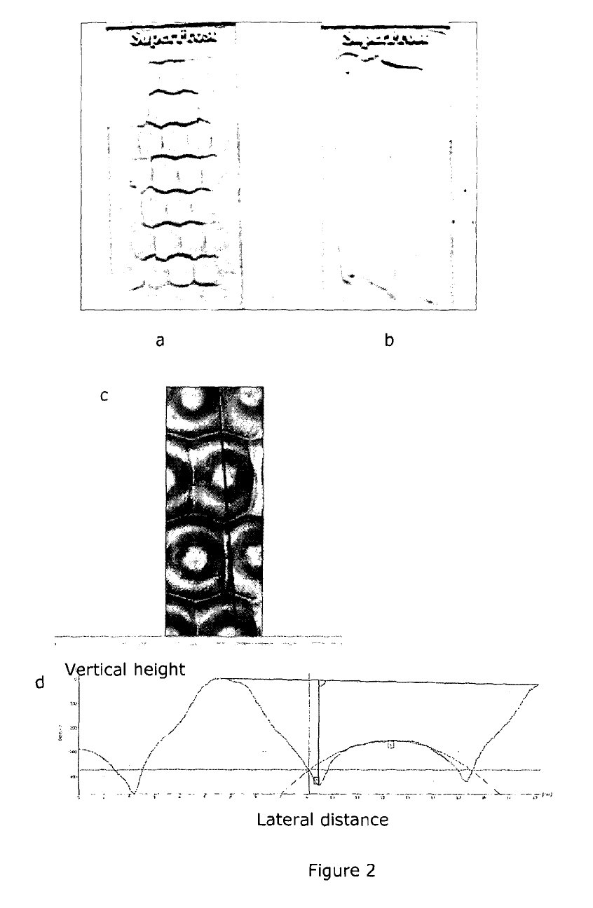

FIG. 2a shows the film from Example 1 which was made using the mask in FIG. 1a, and FIG. 2b shows the film from Example 1 which was made without using a mask;

FIGS. 2c shows the surface pattern of the film of FIG. 2a viewed from the top and FIG. 2d shows a topographical profile of the coating obtained from the trace drawn as a red line on FIG. 2c through the use of a technique of optical microscopy with computer analysis;

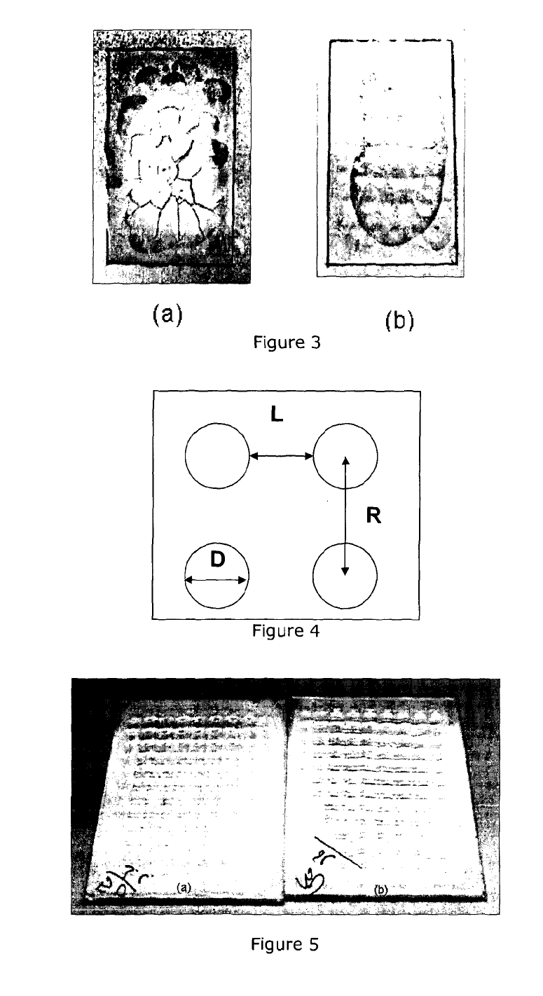

FIG. 3a shows the film of Example 2 which was exposed to IR radiation for twenty minutes and FIG. 3b shows the film of Example 2 which was exposed to IR radiation for thirty-five minutes;

FIG. 4 shows a diagram explaining the meaning of the terms used in Example 3;

FIG. 5a shows the film of Example 4 made from 50 wt. % latex and FIG. 5b shows the film of Example 4 made from 30 wt. % latex;

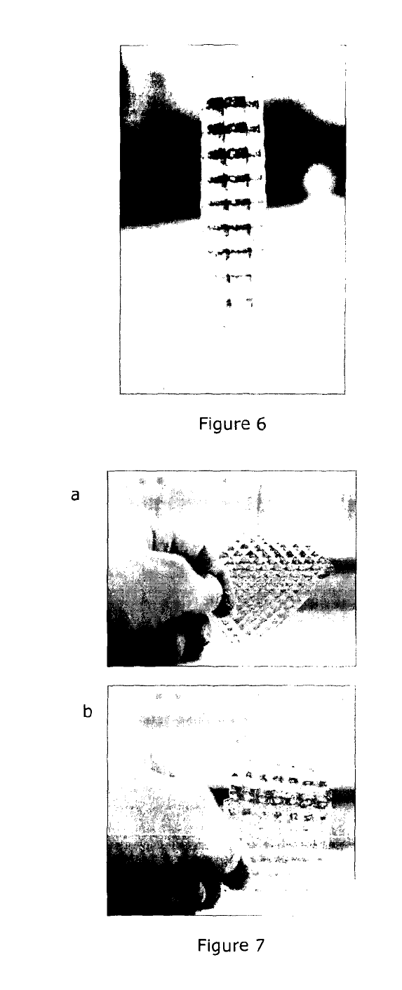

FIG. 6 shows the film of Example 5 rolled into a tube;

FIG. 7a shows the film of Example 6 made using Mask 1 and FIG. 7b shows the film of Example 6 made from Mask 5;

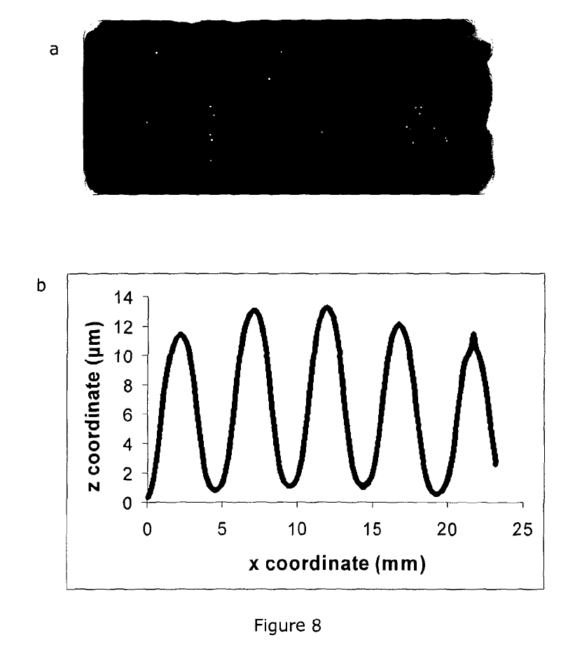

FIG. 8a shows the film of Example 7 made from a polymer solution using Mask 1 and FIG. 8b shows the surface topography obtained from a surface profiler;

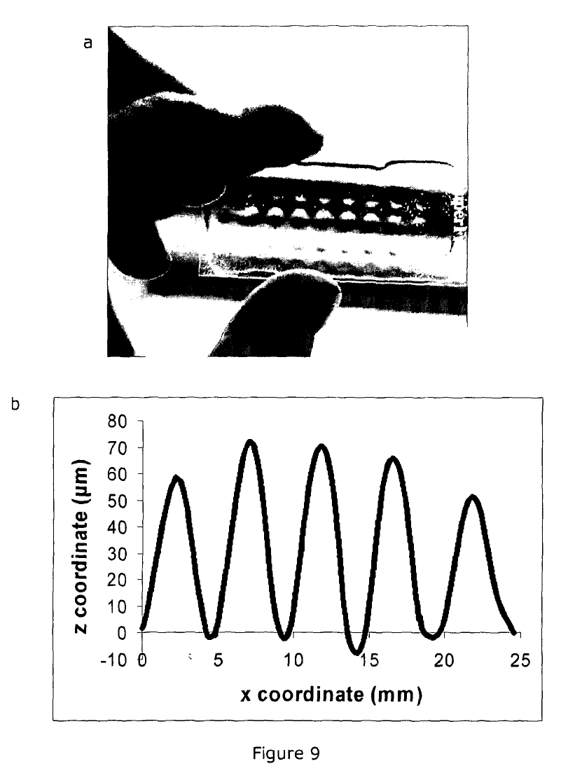

FIG. 9a shows the film of Example 8 made from a polymer solution using Mask 1 and FIG. 9b shows the surface topography obtained from a surface profiler.

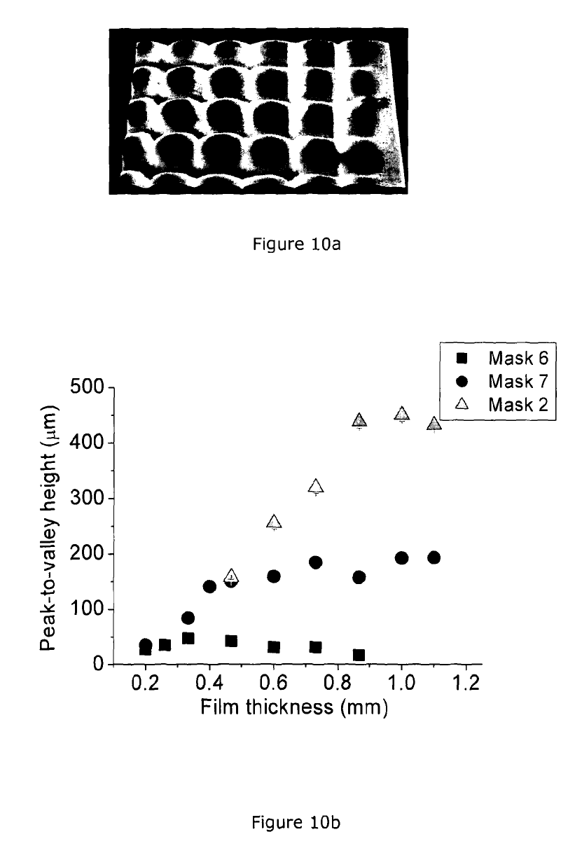

FIG. 10a shows the surface pattern of the film of Example 9 made using Mask 7 with a wet film thickness of 0.33 mm and FIG. 10b shows the peak-to-valley height versus the film thickness for the films of Example 9 made from Masks 2, 6 and 7;

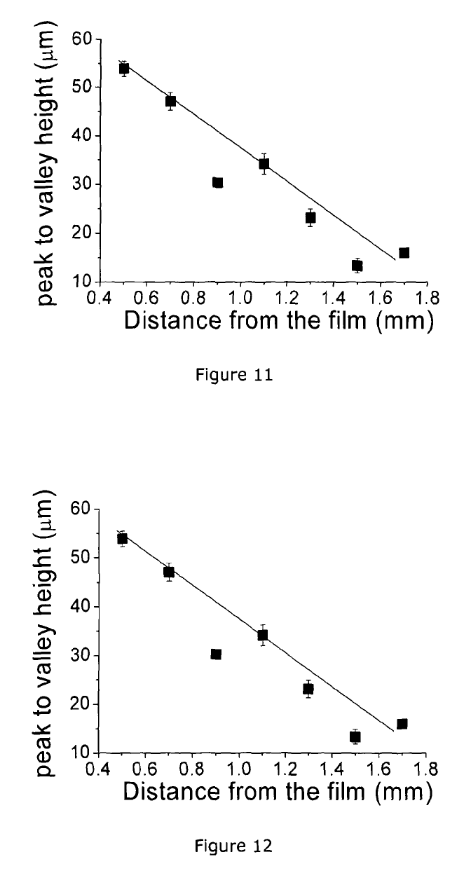

FIG. 11 shows the peak-to-valley height versus the distance from the film for the film of Example 10;

FIG. 12 shows the peak-to-valley height versus the centre-to-centre distance for the films of Example 11 made from Masks 6, 7, 8, 9 and 10;

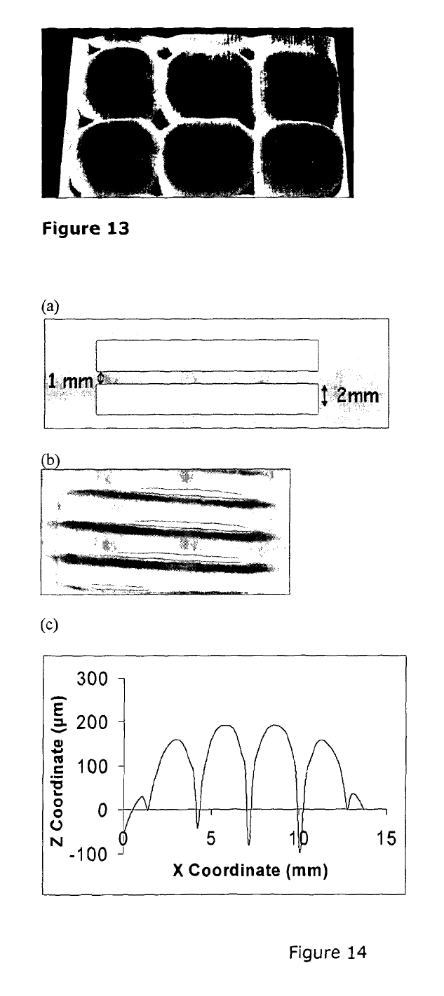

FIG. 13 shows the surface pattern of the film of Example 12;

FIG. 14a shows the mask used in Example 13, FIG. 14b shows the surface pattern of the film of Example 13 and FIG. 14c shows a topographical profile of the film of Example 13;

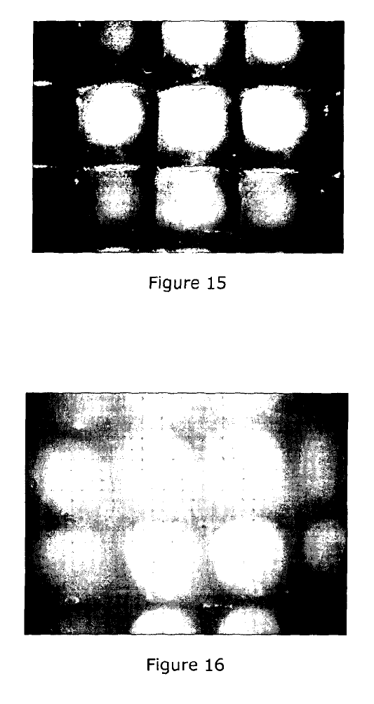

FIG. 15 shows the surface pattern of the film of Example 15; and

FIG. 16 shows the surface pattern of the film of Example 16.

### EXAMPLE 1

A wet latex was made from particles of a copolymer of butyl acrylate, methyl methacrylate and methacrylic acid dispersed in water. The latex was made by a standard method of emulsion polymerisation. The wet latex has a polymer solids content of approximately 50 weight % and a T_{g} of 38° C.

A latex film was formed by casting 1g of the wet latex onto a glass substrate with the aid of a pipette. The resulting wet film was 0.2 mm thick. A mask was placed 2 mm above the wet film. The mask consisted of a sheet of metal having a number of circular perforations arranged in rows. A diagram of the size and arrangement of perforations is shown in FIG. 1a. The mask has d=3 mm, L=2.25 mm and x=4.5 mm.

As shown schematically in FIG. 1b, the masked film was exposed to IR radiation of wavelengths ranging from 700 nm to 1.8 μm emitted from a 250 W IR lamp at a distance of 25 cm for thirty minutes.

The example was then repeated, but without using the mask. A shorter radiation time of 15 minutes was used, this being all that was required because the drying was uniform and from the entire surface of the film.

FIGS. 2a and 2b show the two dried films from this example. FIG. 2d shows the surface pattern of the film of FIG. 2a scanned along the line marked on FIG. 2c. From these figures it can be seen that there is a pattern on the surface of the film shown in FIG. 2a, which takes the form of a number of discrete raised portions arranged in a regular pattern.

### EXAMPLE 2

Example 1 was repeated using a steel substrate instead of a glass substrate. In order to show the effect of the length of exposure to the IR radiation, different exposure times were used. FIG. 3a shows the results of exposing a film to IR radiation when masked with the mask in FIG. 1a for twenty minutes. FIG. 3b shows the results of exposing the masked film to IR radiation for thirty-five minutes. As can be seen, the masked film which was exposed for only twenty minutes is opaque and has cracks. Accordingly, it should be ensured that exposure takes place until the film is completely dried.

### EXAMPLE 3

Example 1 was repeated using a number of different masks. Each of the masks consisted of a sheet of metal having a number of circular perforations arranged in rows. The details of the masks were as follows (see FIG. 4 for a diagram showing the meaning of the terms used):

| | | Centre to | |
|---|---|---|---|
| | | Centre | Edge to Edge |
| | Hole Diameter | Distance | Distance |
| | (mm) - D | (mm) - R | (mm) - L |
| Mask 1 | 3 | 5 | 2 |
| Mask 2 | 4 | 6 | 2 |
| Mask 3 | 5 | 7 | 2 |
| Mask 4 | 3 | 6 | 3 |
| Mask 5 | 3 | 7 | 4 |

The effect of increasing the hole diameter can be seen from the following table:

| | Hole | Diameter | Peak-to-valley |
|---|---|---|---|
| | Diameter, D | of Raised | distance of raised |
| | (mm) | Portion (mm) | portion (mm) |
| Mask 1 | 3 | 3.75 | 0.21 |
| Mask 2 | 4 | 4.23 | 0.23 |
| Mask 3 | 5 | 5.2 | 0.26 |

Thus, increasing the hole diameter increases the diameter of the raised portions on the coating. Increasing the hole diameter also increases the peak-to-valley distance of the raised portion of the coating.

The effect of increasing the hole's centre-to-centre distance can be seen from the following table:

| | Hole Centre-to- | Peak-to-Peak |
|---|---|---|
| | Centre Distance, R | distance of raised |
| | (mm) | portion (mm) |
| Mask 1 | 5 | 5 |
| Mask 4 | 6 | 6 |
| Mask 5 | 7 | 7 |

Thus, the greater the hole spacing, the longer the peak-to-peak distance of the raised portions in the coating.

It was also noted that, for Mask 5, there was a need for almost 50% more exposure time to produce a dried coating.

### EXAMPLE 4

Example 1 was repeated using two different solids contents, a 30 wt. % latex and a 50 wt. % latex.

For the coating made from the 50 wt. % latex, almost 75% of the film area was flat, and 25% was covered with raised portions having a height of around 0.08-0.2 mm (see FIG. 5a). By comparison, for the coating made from the 30 wt. % latex, almost 90% of the coating's surface was covered with raised portions with a height of 0.08-0.21 mm (see FIG. 5b).

Accordingly, it can be seen that, the lower is the solids content, the greater is the area of the raised portions of the coating.

### EXAMPLE 5

A wet latex was made from particles of an acrylic copolymer comprised of methyl methacrylate, butyl acrylate and methacrylic acid dispersed in water. The latex was made by standard methods of emulsion polymerisation. The wet latex has a polymer solids content of 50 weight % and a T_{g} of 0° C.

A latex film was formed by casting 2.7 g of the wet latex onto a glass substrate with the aid of a pipette. The area of the glass substrate is 5 cm by 7.5 cm. The resulting wet film was 200 μm thick. A mask was then placed above the wet film. The mask used was Mask 1 from Example 3.

The masked film was exposed to IR radiation of wavelengths ranging from 700 nm to 1.8 μm from a 250 W IR lamp at a distance of 25 cm for 30 minutes.

The resulting dried film was peeled off of the substrate to create a free-standing and flexible film, which can be rolled into a tube (see FIG. 6).

### EXAMPLE 6

Example 5 was repeated using a different latex with a number of different masks. A wet latex was made from particles of an acrylic copolymer comprised of blend of acrylic monomers dispersed in water. The latex was made by standard methods of emulsion polymerisation. The wet latex has a polymer solids content of 45 weight % and a T_{g} of −10° C.

The resulting dried films are shown in FIG. 7a (Mask 1) and 7b (Mask 5).

### EXAMPLE 7

A polymer solution of poly(3-4 ethylene dioxythiophene)-poly(styrene sulfonate) or PEDOT-PSS in water, with a polymer concentration of 1.3 wt. % solids content (obtained from the Aldrich Chemical Company) was cast onto a glass plate. The dimension of the glass plate was 7.5 cm×2.5 cm.

1 g of the PEDOT-PSS solution was cast with the aid of a pipette. The resulting wet film was approximately 200 μm thick. A mask was then placed above the wet film. The mask used was Mask 1 from Example 3.

The masked film was exposed to IR radiation of wavelengths ranging from 700 nm to 1.8 μm from a 250 W IR lamp at a distance of 25 cm for 45 minutes. A dry film with surface protrusions in a regular pattern resulted (FIG. 8a). The thicker areas of the coating appear darker in the photograph in FIG. 8a.

FIG. 8b shows a topographical profile of the polymer film obtained through the use of profilometry. The lateral distance of the profile is 27 mm. The measured peak-to-valley height of the surface protrusions is greater than 10 μm.

### EXAMPLE 8

A polymer powder of poly(vinyl pyrrolidone) (or PVP) with a molecular weight of 1,300,000 g per mole was obtained from the Sigma-Aldrich Chemical Company.

1 g of the polymer was dissolved in 9 g of deionised water to make a 10 wt. % solution. A polymer film was formed by casting 1 g of the PVP solution onto a glass substrate (7.5 cm×2.5 cm) with the aid of a pipette. The resulting wet film was 200 μm thick. A mask was then placed above the wet film. The mask used was Mask 1 from Example 3.

The masked film was exposed to IR radiation of wavelengths ranging from 700 nm to 1.8 μm from a 250 W IR lamp at a distance of 25 cm for 45 minutes. FIG. 9a shows the dry film with a pattern of surface protrusions appearing as dark spots.

FIG. 9b shows a topographical profile of the polymer film obtained through the use of profilometry. The lateral distance of the profile is 20 mm. The measured peak-to-valley height is greater than 60 μm.

### EXAMPLE 9

Example 1 was repeated using the same latex, but using three different aluminium masks having arrays of holes as shown in FIG. 4. The dimensions of the masks are listed in the table below:

| | Hole | Centre to Centre | Edge to Edge |
|---|---|---|---|
| | diameter | Distance | Distance |
| | (mm) - D | (mm) - R | (mm) - L |
| Mask 2 | 4 | 6 | 2 |
| Mask 6 | 1 | 1.5 | 0.5 |
| Mask 7 | 2 | 3 | 1 |

In order to show the effect of the initial wet thickness of the film on the height of the resulting raised portions on the dry polymer, the amount of the initial cast latex was varied. For the samples made with Mask 2, several samples with initial wet thicknesses in the range from 0.2 mm to 1.2 mm were cast on a glass substrate (2.5 cm×5 cm). The amount of the latex cast for these samples was in the range from 0.42 g to 1.6 g. For Masks 6 and 7, the range of wet thicknesses was the same, however the size of the glass substrate was 3 cm×2.5 cm, and the amount of cast latex was in the range from 0.2 g to 0.95 g.

In all the cases, the mask was placed at a distance of 0.7 mm above the wet film. The mask was placed at a distance of 16.5 cm below the IR lamp. The radiation time under IR radiation was in the range from 15 min. to 50 min. depending on the initial wet thickness of the film. (A longer radiation time is required for thicker films.)

The topography of a film is shown in FIG. 10a as an example. The image was obtained with a 3-D profiler. The red colour represents higher regions and the green and blue colours represent lower regions. This film was made using Mask 7, a wet film thickness of 0.33 mm, and a distance between the mask and wet film of 0.5 mm. Peaks and valleys can be observed, with a peak-to-valley height of 102 μm.

FIG. 10b shows the peak-to-valley height of the raised portions of the polymer surface as a function of the initial wet thickness of the film for the three masks used in this example. In this figure, it can be seen that for Mask 2, for wet film thicknesses up to 0.8 mm, a higher peak-to-valley height of the raised portions is obtained when the initial wet thickness of the film is higher. When the initial wet thickness increases above 0.8 mm, then the peak-to-valley height stays the same. For Mask 7, a similar general trend is observed with a levelling off of the height values when the wet film thickness rises above 0.4 mm. For Mask 6, the highest peak-to-valley height is obtained when the initial wet thickness is 0.33 mm. It is concluded that the peak-to-valley height of the surface texture can be adjusted through the choice of mask dimensions and initial wet film thickness.

### EXAMPLE 10

Example 1 was repeated using the same latex, but using Mask 6 of Example 9. Experiments were conducted in order to show the effect of the distance of the mask from the wet film on the peak-to-valley height of the raised portions of the polymer film. The mask was placed above the wet film at distances in the range from 0.5 mm to 1.7 mm.

A latex film was formed by casting 0.25 g of wet latex onto a glass substrate (3 cm×2.5 cm). The resulting wet film was 0.33 mm thick.

The mask was placed 16.5 cm below the IR lamp. The radiation time under IR radiation was approximately 20 min.

FIG. 11 shows the peak-to-valley height of the raised portions versus the distance of the mask from the film. From this figure it can be seen that when the distance of the mask from the film is higher, then the peak-to-valley height of the raised portions is lower.

### EXAMPLE 11

Example 1 was repeated using the same latex. In order to determine the effect of the centre-to-centre distance of the masks on the peak-to-valley height of the raised portions, a series of masks was used. The geometric dimensions of the masks are listed in the table that follows.

| | Hole | Centre to Centre | Edge to Edge |
|---|---|---|---|
| | diameter | Distance | Distance |
| | (mm) - D | (mm) - R | (mm) - L |
| Mask 6 | 1 | 1.5 | 0.5 |
| Mask 7 | 2 | 3 | 1 |
| Mask 8 | 0.27 | 0.4 | 0.13 |
| Mask 9 | 0.37 | 0.55 | 0.18 |
| Mask 10 | 0.5 | 0.75 | 0.25 |

All the masks were placed 0.5 mm above the wet film. In all the cases, a latex film was formed by casting 0.25 g of wet latex onto a glass substrate (3 cm×2.5 cm). The resulting wet film was 0.33 mm thick.

The sample and the mask were placed at a distance of 16.5 cm below the IR lamp. The radiation time under the IR lamp was approximately 20 min.

FIG. 12 shows the peak-to-valley height of the raised portions as a function of the centre-to-centre distance for each of the masks. From this figure, it can be seen that the peak-to-valley height of the raised portions is higher when the centre-to-centre distance is higher.

### EXAMPLE 12

Example 1 was repeated using the same latex. Two masks were used together in order to achieve a patterned dried polymer surface with two sizes of surface topography. Mask 2 (used in Example 3) was placed directly above Mask 10 (used in Example 11), with the two masks in contact. The bottom mask was placed 0.5 mm above the wet film.

A latex film was formed by casting 0.2 g of wet latex onto a glass substrate (3 cm×2.5 cm). The resulting wet film was 0.26 mm thick.

The sample and the mask were placed 16.5 cm below the IR lamp. The radiation time under IR radiation was approximately 20 min.

FIG. 13 shows the resulting film with two patterns overlayed. There is an array of smaller protuberances on top of larger features. Thus, it is shown that surfaces with hierarchical length scales of texture can be obtained with suitable mask patterns.

### EXAMPLE 13

Example 1 was repeated using the same latex. The only difference is that a mask with long, rectangular holes was used in order to achieve a linear pattern. FIG. 14a shows a diagram of the aluminium mask used. The white blocks represent the holes in the mask.

A latex film was formed by casting 0.3 g of wet latex onto a glass substrate (2.5 cm×1.5 cm). The resulting wet film was 0.53 mm thick. The mask was placed 0.5 mm above the wet film. The mask was placed 16.5 cm below the IR lamp. The radiation time under IR radiation was approximately 20 min.

The resulting dried film had a linear pattern on its surface. A photograph of the polymer film is shown in FIG. 14b. Linear ridges were created on the surface. Their length and widths are similar to that of the mask.

FIG. 14c shows a topographical profile of the resulted patterned film obtained through profilometry. This measurement confirms that there are surface corrugations with maximum peak-to-valley heights of approximately 300 μm.

### EXAMPLE 14

Example 1 was repeated using five different latexes. The latex was prepared by standard methods of emulsion polymerisation. The glass transition temperature (T_{g}), particle size, and solid contents of the latexes were as listed in the table below. Latex C in the table is the same latex used in Example 1. Latexes A and B have the same composition as Latex C. Latex D has a composition that is similar to A, except it contains a greater proportion of butyl acrylate and a lower proportion of methyl methacrylate, so that it has a lower glass transition temperature than A, B and C. Latex E is a latex in which the copolymer was made from butyl acrylate and methyl methacrylate in a 1:1 weight ratio.

A series of 40 samples were prepared in order to study the effects of particle size, use or not of IR radiation, solids content, and addition of poly(3,4-ethylenedioxythiopene)/poly(styrene sulfonate), known as PEDOT:PSS, which was obtained from the Sigma-Aldrich Company. PEDOT:PSS absorbs infrared radiation strongly. Therefore the temperature of a latex increases more under infrared radiation when it contains PEDOT:PSS. A higher latex temperature leads to a faster evaporation rate of water. A higher concentration of PEDOT:PSS leads to a faster evaporation rate of water.

Either Mask 6 or 7 of Example 11 was used in Example 14. The mask was placed 0.7 mm above the wet film.

A latex film was formed by casting 0.4 g of wet latex onto a glass substrate (3 cm×2.5 cm). The resulting wet film was 0.53 mm thick. The mask was placed 16.5 cm below the IR lamp. The radiation time under IR radiation was approximately 20 min.

The measured peak-to-valley heights of the raised portions are listed in the table below. This example shows that each of the parameters has an effect on the peak-to-valley height of the surface topography. This example shows that when an IR lamp is not used to increase the water evaporation rate, a flat polymer surface results. (Peak-to-valley height is 0 μm). Therefore, it is concluded that it is essential to use infrared heating in order to obtain a topographically patterned surface.

The maximum peak-to-valley height was obtained when 4 wt. % PEDOT:PSS was added to the latex and it was irradiated with IR radiation under a mask with R=3 mm and D=2 mm. This example shows that a wide range of surface topography can be obtained by varying the process parameters.

| | | | | | | | | PEDOT: | Peak-to- | Standard |
|---|---|---|---|---|---|---|---|---|---|---|
| | | | Particle | Polymer | | | IR | PSS | valley | deviation of |
| Sample | | T_{g} | size | content | R | D | lamp | added | height | peak-to-valley |
| Number | Colloid | (° C.) | (nm) | (Wt, %) | (mm) | (mm) | used? | (wt. %) | (μm) | height (μm) |
| 1 | Latex D | 13.4 | 420 | 50 | 3 | 2 | No | 0 | 119 | 9.1 |
| 2 | Latex D | 13.4 | 420 | 50 | 3 | 2 | Yes | 0 | 132.3 | 7.3 |
| 3 | Latex D | 13.4 | 420 | 50 | 3 | 2 | Yes | 2 | 342.2 | 16.7 |
| 4 | Latex D | 13.4 | 420 | 50 | 3 | 2 | Yes | 4 | 350.8 | 12.5 |
| 5 | Latex E | 6 | 28 | 18 | 3 | 2 | No | 0 | 30.8 | 5 |
| 6 | Latex E | 6 | 28 | 18 | 3 | 2 | Yes | 0 | 135.8 | 8.7 |
| 7 | Latex E | 6 | 28 | 18 | 3 | 2 | Yes | 2 | 108.3 | 10.2 |
| 8 | Latex E | 6 | 28 | 18 | 3 | 2 | Yes | 4 | 142.8 | 53 |
| 9 | Latex E | 6 | 28 | 18 | 1.5 | 1 | No | 0 | 0 | 0 |
| 10 | Latex E | 6 | 28 | 18 | 1.5 | 1 | Yes | 0 | 39.5 | 7.9 |
| 11 | Latex E | 6 | 28 | 18 | 1.5 | 1 | Yes | 1.5 | 32.2 | 4.8 |
| 12 | Latex E | 6 | 28 | 18 | 1.5 | 1 | Yes | 4 | 42.3 | 12.4 |
| 13 | Latex D | 13.4 | 420 | 18 | 1.5 | 1 | No | 0 | 0 | 0 |
| 14 | Latex D | 13.4 | 420 | 18 | 1.5 | 1 | Yes | 0 | 31.1 | 8.3 |
| 15 | Latex D | 13.4 | 420 | 18 | 1.5 | 1 | Yes | 1.5 | 81.3 | 8.6 |
| 16 | Latex D | 13.4 | 420 | 18 | 1.5 | 1 | Yes | 4 | 83.2 | 25.2 |
| 17 | Latex A | 36.4 | 160 | 50 | 3 | 2 | Yes | 0 | 226.46 | 22.1 |
| 18 | Latex B | 36.2 | 280 | 50 | 3 | 2 | Yes | 0 | 199.4 | 5.6 |
| 19 | Latex C | 37.9 | 420 | 50 | 3 | 2 | Yes | 0 | 177.4 | 7.5 |
| 20 | Latex A | 36.4 | 160 | 50 | 3 | 2 | Yes | 2 | 224.4 | 43.2 |
| 21 | Latex B | 36.2 | 280 | 50 | 3 | 2 | Yes | 2 | 306.2 | 6 |
| 22 | Latex C | 37.9 | 420 | 50 | 3 | 2 | Yes | 2 | 191.4 | 13.1 |
| 23 | Latex A | 36.4 | 160 | 50 | 3 | 2 | Yes | 4 | 287.5 | 16.4 |
| 24 | Latex B | 36.2 | 280 | 50 | 3 | 2 | Yes | 4 | 318.5 | 15.3 |
| 25 | Latex C | 37.9 | 420 | 50 | 3 | 2 | Yes | 4 | 357.6 | 11.6 |
| 26 | Latex A | 36.4 | 160 | 50 | 1.5 | 1 | Yes | 0 | 89 | 13.3 |
| 27 | Latex B | 36.2 | 280 | 50 | 1.5 | 1 | Yes | 0 | 57.1 | 19.8 |
| 28 | Latex C | 37.9 | 420 | 50 | 1.5 | 1 | Yes | 0 | 50.9 | 12.9 |
| 29 | Latex A | 36.4 | 160 | 50 | 1.5 | 1 | Yes | 1.5 | 99.4 | 16.6 |
| 30 | Latex B | 36.2 | 280 | 50 | 1.5 | 1 | Yes | 1.5 | 87.1 | 20 |
| 31 | Latex C | 37.9 | 420 | 50 | 1.5 | 1 | Yes | 1.5 | 113 | 9.24 |
| 32 | Latex A | 36.4 | 160 | 50 | 1.5 | 1 | Yes | 4 | 65.7 | 10.9 |
| 33 | Latex B | 36.2 | 280 | 50 | 1.5 | 1 | Yes | 4 | 97.8 | 21.6 |
| 34 | Latex C | 37.9 | 420 | 50 | 1.5 | 1 | Yes | 4 | 87.8 | 22.8 |
| 35 | Latex A | 36.4 | 160 | 18 | 1.5 | 1 | Yes | 0 | 5.74 | 3.27 |
| 36 | Latex B | 36.2 | 280 | 18 | 1.5 | 1 | Yes | 0 | 25.2 | 8.46 |
| 37 | Latex C | 37.9 | 420 | 18 | 1.5 | 1 | Yes | 0 | 28.4 | 3.66 |
| 38 | Latex A | 36.4 | 160 | 18 | 1.5 | 1 | Yes | 4 | 112 | 16.4 |
| 39 | Latex B | 36.2 | 280 | 18 | 1.5 | 1 | Yes | 4 | 77.2 | 22.3 |
| 40 | Latex C | 37.9 | 420 | 18 | 1.5 | 1 | Yes | 4 | 99.9 | 11.4 |

### EXAMPLE 15

Patterned films were prepared following the procedure in Example 1 using blends of two latexes, each with a different average particle size. Latex C, which was used in Example 14, (with a particle size of 420 nm) was blended with a polystyrene latex with a particle size of 50 nm, which was obtained from Polysciences, Inc. with a trade name of Fluoresbrite® YG Microspheres. The polymer was labelled with a fluorescent dye so that the particles can be distinguished from the particles of Latex C. Approximately 100 μL of the 50 nm latex was blended with 5 mL of Latex C.

A latex film was formed by casting 0.4 g of the blended wet latex onto a glass substrate (3 cm×2.5 cm). The resulting wet film was 0.53 mm thick. Mask 7 was placed approximately 0.7 mm above the wet film and approximately 16.5 cm below the IR lamp. The radiation time under IR radiation was approximately 20 min.

FIG. 15 shows a photograph of the resulting film obtained using a microscope under ultraviolet (UV) illumination. An area of approximately 11 mm×7 mm is shown in the photograph. It can be observed that the resulting film has a non-uniform distribution of fluorescent particles laterally in the plane of the polymer coating. The fluorescent polystyrene appears lighter in the photograph. The concentration is greater in the raised portions of the coating.

### EXAMPLE 16

This same procedure was repeated again using Latex E (with a particle size of 28 nm) instead of Latex C. A photograph (obtained in a microscope under UV illumination) of the resulting film is shown in FIG. 16. An area of approximately 8 mm×10 mm is shown. The fluorescent polystyrene particles are concentrated at regularly-spaced regions in the film. These regions are located at the positions that were under the holes in the mask. The surface of the coating is raised at these same positions.

This example shows that latexes of different particle sizes can be blended and used to make a film. The particles are non-uniformly distributed in the dried latex film. This example demonstrates a method by which the optical and dielectric properties of a coating can be periodically modulated.

1. A method of making a patterned dried polymer from a polymer solution or polymer dispersion, the method comprising the step of placing a mask above the polymer solution/dispersion so that there are exposed areas of polymer solution/dispersion and unexposed areas of polymer solution/dispersion, and irradiating the masked polymer solution/dispersion with infrared radiation.

2. A method according to claim 1, wherein the patterned dried polymer is made from a polymer dispersion in the form of a latex.

3. A method according to claim 2, wherein the latex is a hard latex having a T_{g} in the range from 20° C. to 100° C.

4. A method according to claim 2, wherein the latex is a soft latex having a T_{g} in the range from −50° C. to 20° C.

5. A method according to claim 1, wherein the exposure conditions are such that the temperature of the polymer is raised above its glass transition temperature.

6. A method according to claim 5, wherein the exposure conditions are such that the temperature of the polymer is raised at least 15° C. above its glass transition temperature.

7. A method according to claim 1, wherein the wavelength of the infrared radiation is in the range from 0.7 μm to 30 μm, more preferably in the range from 0.7 μm to 1.8 μm.

8. A method according to claim 1, wherein the wavelength of the infrared radiation is substantially the same as the wavelength at which the polymer has the greatest absorption coefficient or at which the water is strongly absorbing of the infrared radiation.

9. A method according to claim 2, wherein the masked latex is exposed to the infrared radiation until the latex is completely dried.

10. A method according to claim 2, wherein the distance of the latex from the infrared source is in the range between 1 and 100 cm, more preferably 5 and 30 cm, and most preferably 15 to 20 cm.

11. A method according to claim 2, wherein the latex is in the form of a coating and the thickness of the dried coating is in the range between 0.5 μm and 1 cm thick, more preferably between 2 μm and 1 mm thick and most preferably in the range between 10 μm and 300 μm thick.

12. A method according to claim 2, wherein the solids content of the latex is in the range from 10 weight percent to 80 weight percent, preferably in the range from 30 weight percent to 60 weight percent, and more preferably in the range from 45 weight percent to 55 weight percent.

13. A method according to claim 1, wherein the distance between the latex and the mask is in the range from 0.01 mm to 10 cm, preferably in the range from 0.1 mm to 10 mm, more preferably in the range 0.2 to 3 mm.

14. A method according to claim 1, wherein the mask has perforations with a diameter in the range from 0.01 mm to 10 cm, preferably in the range from 0.1 mm to 1 cm, and more preferably in the range from 0.5 mm to 5 mm.

15. A method according to claim 1, wherein the mask has perforations which are square, circular, oval, triangular, rectangular, rhomboidal, polygonal, or in the shape of a logo.

16. A method according to claim 1, wherein the mask has dimensions ranging from 1 mm to 10 m, preferably in the range from 1 cm to 1 m, and more preferably in the range from 1 cm to 20 cm.

17. A method according to claim 2, wherein the mask fully covers the latex.

18. A method according to claim 2, wherein the mask is made of a material that blocks the transmission of infrared radiation.

19. A method according to claim 2, wherein the latex is cast on a substrate made of glass, steel, aluminium, metal alloys, plastic, card or wood.

20. A method according to claim 19, wherein the latex is removed from the substrate to make a free-standing film.

21. A method according to claim 2, wherein the latex comprises a mixture of two or more latexes, each having a different average particle size.

22. A method according to claim 2, wherein the latex comprises one or more of the following: metallic nanoparticles, semiconducting particles, coloured particles, fluorescent particles, an additional infrared absorber.

23. (canceled)

24. A patterned dried polymer prepared by a method according to claim 1.

25. (canceled)
